(19) United States
(12) Patent Application Publication
(10) Pub. No.: US 2007/0151516 A1
(43) Pub. Date: Jul. 5, 2007

(54) Chemical vapor deposition apparatus and electrode plate thereof

(76) Inventors: Kam S. Law, San Jose, CA (US); Masato Toshima, Saratoga, CA (US)

Correspondence Address: BIRCH STEWART KOLASCH & BIRCH, PO BOX 747, FALLS CHURCH, VA, 22040-0747, US

(21) Appl. No.: 11/322,334

(22) Filed: Jan. 3, 2006

(51) Int. Cl. C23C 16/00

(52) U.S. Cl. 118/723 E

(57) ABSTRACT

The vapor deposition apparatus has an electrode plate, which is capable of being easily produced, reducing a production cost and enhancing the ionization efficiency of the reactants. The chemical vapor deposition apparatus comprises a processing chamber and the electrode plate provided in the processing chamber, reactants are spouted from the electrode plate toward the work piece with applying radio frequency energy between the electrode plate and the work piece so as to produce plasma there between to process the work piece. The electrode plate has a plate proper including a plurality of gas spouts, which run through the plate proper in the thickness direction thereof, and the gas spouts are opened in inner bottom faces of any grooves, which are formed in a surface of the plate proper facing the work piece and extended to linearly transect the plate proper.

### BACKGROUND OF THE INVENTION

The present invention relates to a chemical vapor deposition apparatus, in which a film is formed on a substrate by producing plasma in a processing chamber, and an electrode plate used in the apparatus.

Chemical vapor deposition apparatuses have been widely used for forming films of various substances on substrates. A conventional chemical vapor deposition apparatus is shown in FIG. 6. The apparatus is disclosed in Japanese Patent Gazette No. 1-139771. In the apparatus, a gas inlet 12 for introducing a film forming reactants are provided in an upper part of a processing chamber 10, an electrode plate 14 including gas spouts for uniformly spouting the gas is provided under the gas inlet 12, and a work piece 20 is provided to face the electrode plate 14. With this structure, a film can be formed on the work piece 20.

The work piece 20 supported by a supporting plate 22. The supporting plate 22 is vertically moved between an upper position, at which the work piece 20 is located in an opening 24a of a shielding plate 24 to form the film, and a lower position, at which the work piece 20 is transferred.

To form the film, the work piece 20 is moved upward until entering the opening 24a. Then, the film forming reactants are introduced into the processing chamber 10 via the gas inlet 12. Further, high frequency waves are applied to the electrode plate 14 so as to produce plasma in the processing chamber 10, so that the film can be formed on the surface of the work piece 20.

If a nitrogen gas is used for forming a film of a nitride, e.g., silicon nitride, as one of the reactants, a film-forming rate is low because nitrogen is difficult to dissociate. Therefore, ammonia has been used, as one of the reactants, so as to form a nitride film. According to said Japanese patent gazette, in case of using the gas, such as a nitrogen gas, which is difficult to dissociate, for forming a film, an electrode plate 30 shown in FIGS. 7A and 7B is used to increase the film forming rate.

The electrode plate 30 has a plate proper including a plurality of gas spouts 32, which run through a plate proper 30a in the thickness direction thereof, and female tapered parts 34 are respectively formed at ends of the gas spouts 32, which face the work piece 20. By forming the female tapered parts 34 at the ends of the gas spouts 32, dissociation of reactants can be accelerated. Therefore, even in case of using the gas, such as a nitrogen gas, which is difficult to dissociate, as one of the reactants, the film-forming rate can be increased.

However, it takes a long time to produce the electrode plate 34 in which the female tapered part 34 is formed at the end of each gas spout 32. As shown in FIG. 7B, the gas spouts 32 are densely arranged in an entire planar area of the plate proper 30a. Thus, if the work piece 20 is large, the electrode plate 30 must be large, too. For example, thousands of the gas spouts 32 must be formed in one electrode plate 30. By increasing the number of the gas spouts 32, even if the gas spouts 32 and the female tapered parts 34 are formed in the electrode plate 30 by an automatic processing machine, it takes a very long time, e.g., several days.

### SUMMARY OF THE INVENTION

The present invention was conceived to solve the above-described problems.

An object of the present invention is to provide a vapor deposition apparatus having an electrode plate, which is capable of being easily produced, reducing a production cost and accelerating dissociation of a reaction gas, and the electrode plate for the apparatus.

To achieve the object, the present invention has following structures.

Namely, the chemical vapor deposition apparatus of the present invention comprises a processing chamber and an electrode plate provided in the processing chamber, a work piece is provided in the processing chamber to face the electrode plate parallel, reactants are spouted from the electrode plate toward the work piece with applying radio frequency energy between the electrode plate and the work piece so as to produce plasma there between to process the work piece, and the chemical vapor deposition apparatus is characterized in,

That the electrode plate has a plate proper including a plurality of gas spouts, which run through the plate proper in the thickness direction thereof, and

That the gas spouts are opened in inner bottom faces of any grooves, which are formed in a surface of the plate proper facing the work piece and extended to linearly transect the plate proper.

In the apparatus, a planar arrangement of the gas spouts in the plate proper and all of the grooves may be mutually arranged parallel (FIG. 2B, FIG. 3B).

In the apparatus, a planar arrangement of the gas spouts in the plate proper and the grooves may be divided into three groups, in each of which the grooves are arranged parallel and which are mutually crossed at crossing angles of 60 degrees (FIG. 5B).

In the apparatus, a planar arrangement of the gas spouts in the plate proper and the grooves may be divided into two groups, in each of which the grooves are arranged parallel and which are mutually crossed at crossing angles of 90 degrees (FIG. 4B).

Each of the grooves may have a tapered sectional shape, in which a width of an open end is greater than that of an inner end (FIG. 2C). With this structure, the grooves can be easily formed; reactants can be effectively dissociated so that the work piece can be effectively processed.

Each of the grooves may have an inverse tapered sectional shape, in which a width of an open end is smaller than that of an inner end (FIG. 3C). With this structure, the reactants can be effectively dissociated so that the work piece can be effectively processed.

In the chemical vapor deposition apparatus of the present invention, the gas spouts are opened in the inner bottom faces of the grooves, which are formed in the plate proper of the electrode plate, so that the dissociation of the reactants can be accelerated. Therefore, a film can be formed with reactants, which are difficult to dissociate. Further, the electrode plate of the present invention is capable of accelerating the dissociation of the reactants, being easily produced with a large number of the gas spouts and reducing the production cost.

### BRIEF DESCRIPTION OF THE DRAWINGS

Embodiments of the present invention will now be described by way of examples and with reference to the accompanying drawings, in which:

FIG. 1 is a schematic sectional view of a chemical vapor deposition apparatus of the present invention;

FIG. 2A is a sectional view of a first embodiment of an electrode plate;

FIG. 2B is a plan view of the first embodiment of the electrode plate;

FIG. 2C is a partial sectional view of grooves;

FIG. 3A is a sectional view of a second embodiment of the electrode plate;

FIG. 3B is a plan view of the second embodiment of the electrode plate;

FIG. 3C is a partial sectional view of grooves;

FIG. 4A is a sectional view of a third embodiment of the electrode plate;

FIG. 4B is a plan view of the third embodiment of the electrode plate;

FIG. 4C is a partial sectional view of grooves;

FIG. 5A is a sectional view of a fourth embodiment of the electrode plate;

FIG. 5B is a plan view of the fourth embodiment of the electrode plate;

FIG. 5C is a partial sectional view of grooves;

FIG. 6 is a schematic sectional view of the conventional chemical vapor deposition apparatus;

FIG. 7A is a sectional view of the conventional electrode plate taken along a line A-A of FIG. 7B; and

FIG. 7B is a plan view of the conventional electrode plate.

### DETAILED DESCRIPTION OF THE EMBODIMENTS

Preferred embodiments of the present invention will now be described in detail with reference to the accompanying drawings.

(Structure of The Chemical Vapor Deposition Apparatus)

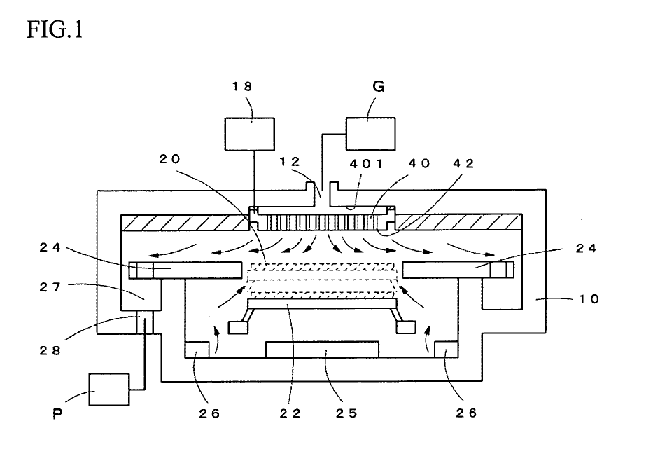

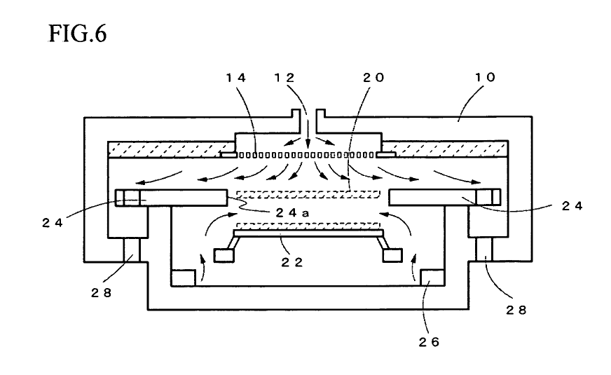

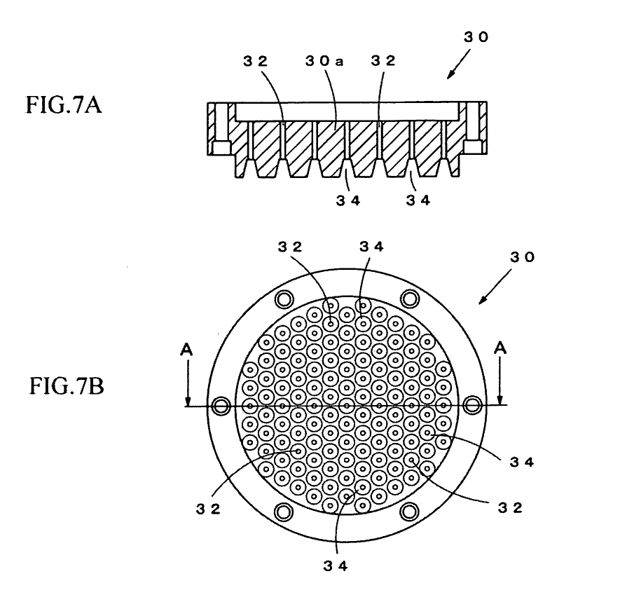

FIG. 1 is a schematic sectional view of the chemical vapor deposition apparatus of the present invention. The basic structure of the apparatus of the present embodiment is similar to that of the conventional chemical vapor deposition apparatus shown in FIG. 6.

Namely, a work piece 20 is processed in a processing chamber 10. An electrode plate 40 is provided in the processing chamber 10, and the work piece 20 is provided in the processing chamber 10 to face the electrode plate 40 parallel. Plasma is produced in the processing chamber 10 so as to form a film on a surface of the work piece 20.

A reservoir space 401 is formed in an upper part of the electrode plate 40 so as to allow mixing of reactants prior to exit electrode plate into the processing chamber 10. A gas inlet 12 is formed in the processing chamber 10, in which the electrode plate 40 is electrically insulated from the processing chamber 10, and communicated with the reservoir space 401. The gas inlet 12 communicated with a gas-supplying unit G, which supplies reactants. The reactants are supplied from the unit G when a prescribed step of a film forming process is performed.

The work piece 20 is supported by a supporting plate 22, which faces the electrode plate 40. The supporting plate can be the heater 25 itself. The supporting plate 22 is vertically moved between an upper position, at which the supporting plate 22 enters an opening 24a of a shielding plate 24, and a lower position, which is located under the shielding plate 24 and at which the work piece 20 is transferred. The size of the opening 24a is slightly larger than the work piece 20.

At the lower position (transfer position), the work piece 20 is transferred into the processing chamber 10 by a transfer mechanism (not shown). After forming the film, the work piece 20 is transferred outside from the processing chamber by the same mechanism. A heater 25 provides heating for the work piece 20.

The feature of the chemical vapor deposition apparatus of the present embodiment is the electrode plate 40 facing the work piece 20. The surface of the work piece 20 is arranged to face a surface of the electrode plate 40 parallel. To apply plasma to the entire surface of the work piece 20, a planar area of the electrode plate 40 is corresponded to or made broader than that of the work piece 20. The electrode 40 is connected to a radio frequency wave generator 18.

(First Embodiment of The Electrode Plate)

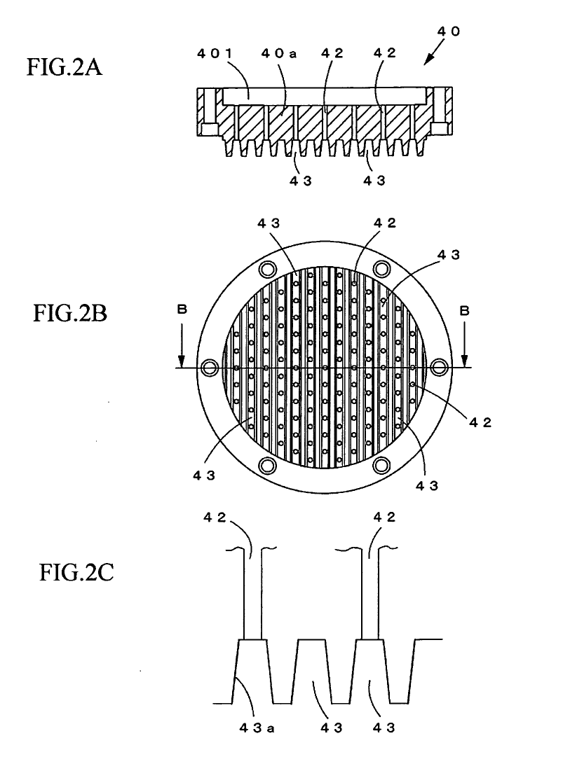

A first embodiment of the electrode plate 40 will be explained with reference to FIGS. 2A-2C. The electrode plate 40 has a plate proper 40a including a plurality of gas spouts 42, which run through the plate proper 40a in the thickness direction thereof. A plurality of gas spouts 42 are opened in the surface of the electrode plate 40 facing the work piece 20. Parallel grooves 43 are formed in the surface of the electrode plate 40 and extended to linearly transect the electrode plate 40. Each of the gas spouts 42 is included in the parallel groove 43.

FIG. 2A is a sectional view taken along a line B-B of FIG. 2B, and FIG. 2C is an enlarged partial sectional view of the grooves 43.

A planar arrangement of the gas spouts 42 in the electrode plate 40 is shown in FIG. 2B. Gas spouts 42 are included in any linear grooves 43.

As shown in FIG. 2C, each of the grooves 43 has a trapezoid sectional shape or a tapered sectional shape, in which a width of the inner face 43a is gradually made wider toward an open end facing the work piece 20. Namely, the inner face 43a is formed into a tapered face. Each of the gas spouts 42 is opened in an inner bottom face of the groove 43.

In the present embodiment, the grooves 43 can be easily formed in the plate proper 40a by a milling cutter. Since the grooves 43 are linearly extended from one edge of the plate proper 40a to the other edge thereof, the grooves 43 can be formed by linearly moving the milling cutter. In comparison with the conventional method of forming a large number of the female tapered part 34 corresponding to the gas spouts 32, the method of forming the grooves 43 is highly efficient. Even if the electrode plate 40 is a large electrode plate with a large number of the gas spouts 42, the electrode plate 40 of the present embodiment can be easily produced.

(Second Embodiment of The Electrode Plate)

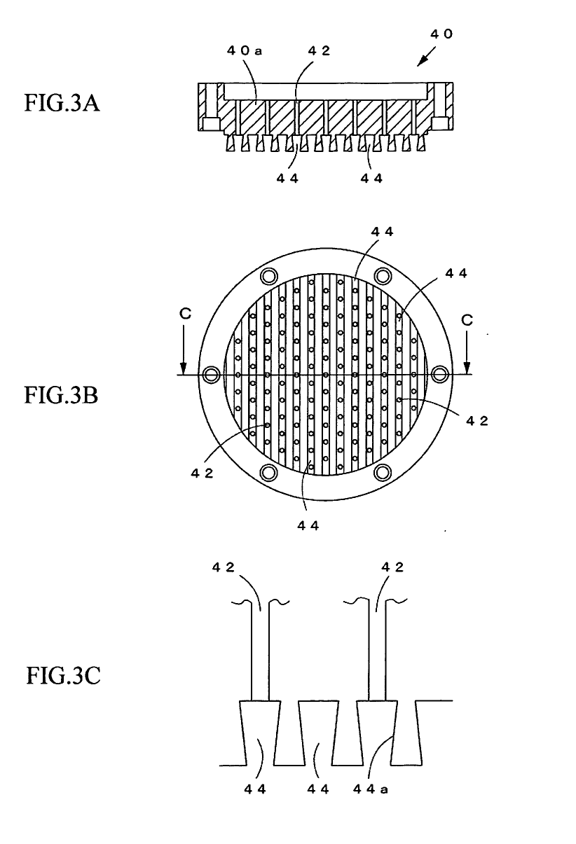

A second embodiment of the electrode plate 40 will be explained with reference to FIGS. 3A-3C. FIG. 3A is a sectional view taken along a line C-C of FIG. 3B, and FIG. 3C is an enlarged partial sectional view of grooves 44 of the electrode plate 40. The electrode plate 40 has a plate proper 40a including a plurality of gas spouts 42, which run through the plate proper 40a in the thickness direction thereof, and a plurality of the gas spouts 42 are opened in the surface of the electrode plate 40 facing the work piece 20, as well as the first embodiment. The parallel grooves 44 are formed in the surface of the electrode plate 40, similar to the first embodiment shown in FIG. 2A-2C, and each of the gas spouts 42 are included in the parallel groove 44. Namely, all of the gas spouts 42 formed in the plate proper 40a are included in any grooves 44. The feature of the second embodiment is sectional shapes of the grooves 44. As shown in FIG. 3C, the grooves 44 are dovetail grooves or inverse tapered grooves, whose sectional shapes are trapezoid. A width of each groove 44 is gradually made narrower toward an open end. Namely, inner faces 44a are formed into invert tapered faces. The grooves 44 having inverse tapered sectional shapes can be easily formed by a dove tail-shaped milling cutter. By forming the dovetail grooves 44 in the electrode plate 40, the dissociation of the reaction gas can be accelerated.

In the conventional electrode plate, it is impossible to form inverse tapered parts at ends of the gas spouts 42. However, in the present invention, the grooves 44 linearly transect the surface of the electrode plate 40, so the inverse tapered grooves 44 can be easily formed. Further, in comparison with the conventional method of forming a large number of the female tapered part 34, the method of forming the grooves 44 is capable of highly efficiently producing the electrode plate 40.

(Third Embodiment of The Electrode Plate)

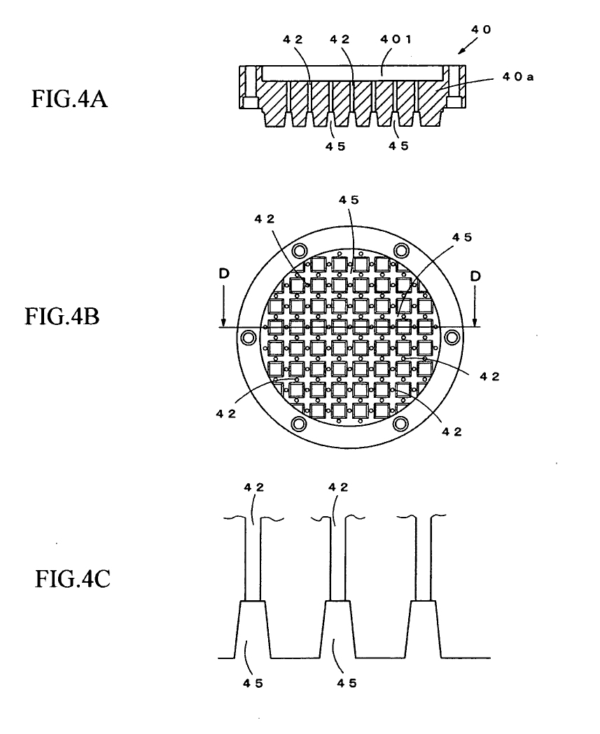

A third embodiment of the electrode plate 40 will be explained with reference to FIGS. 4A-4C. FIG. 4A is a sectional view taken along a line D-D of FIG. 4B, and FIG. 4C is an enlarged partial sectional view of grooves 45 of the electrode plate 40. A plurality of gas spouts 42 is formed in a plate proper 40a of the electrode plate 40. The grooves 45 are divided into two groups, in each of which lines of the grooves 45 are arranged parallel and which are mutually crossed at crossing angles of 90 degrees.

As shown in FIG. 4C, each of the grooves 45 has a trapezoid sectional shape or a tapered sectional shape, in which a width is gradually made wider toward an open end, and the gas spouts 42 are opened in inner bottom faces of the grooves 45. Since the gas spouts 42 are opened in the tapered grooves 45, the reaction gas can be effectively dissociated. Note that, the grooves 45 may have inverse tapered sectional shapes.

In the electrode plate 40 of the present embodiment too, the grooves 45 linearly intersect the surface of the electrode plate 40. Therefore, a milling cutter can easily form the grooves 45. To form the grooves 45, firstly the parallel grooves 45 of the first group are formed in a first direction, and then the parallel grooves 45 of the other group are formed in a second direction perpendicular to the first direction.

(Fourth Embodiment of The Electrode Plate)

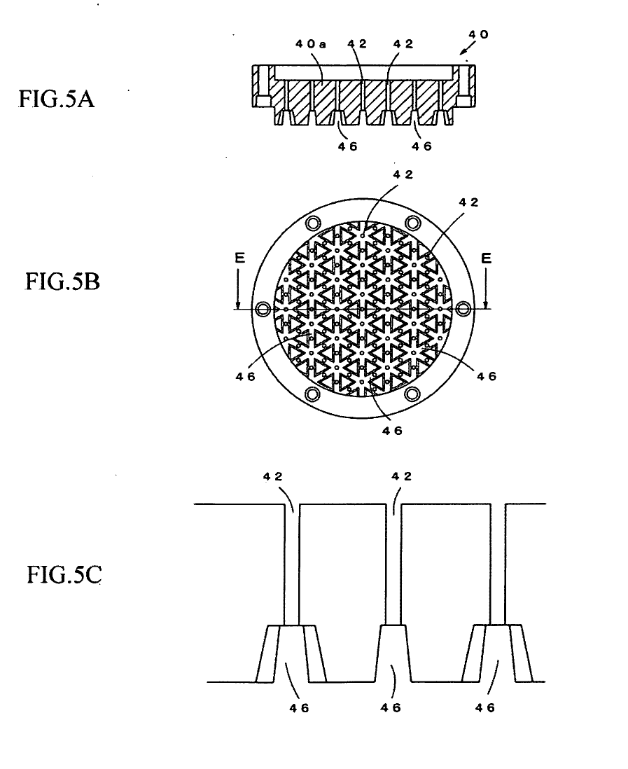

A fourth embodiment of the electrode plate 40 will be explained with reference to FIGS. 5A-5C. FIG. 5A is a sectional view taken along a line E-E of FIG. 5B, and FIG. 5C is an enlarged partial sectional view of grooves 46 of the electrode plate 40. A plurality of gas spouts 42 is formed in a plate proper 40a of the electrode plate 40. The grooves 46 are divided into three groups, in each of which lines of the grooves 46 are arranged parallel and which are mutually crossed at crossing angles of 60 degrees. The grooves 46 are radially extended from each gas spout 42, which is located at a cross point of the grooves 46.

The grooves 46 are formed by the steps of: grooving the parallel grooves 46 of a first group in a first direction; grooving the parallel grooves 46 of a second group in a second direction, which is angularly shifted 60 degrees from the first direction; and grooving the parallel grooves 46 of a third group in a third direction, which is angularly shifted 60 degrees from the second direction.

As shown in FIG. 5C, each of the grooves 46 has a trapezoid sectional shape or a tapered sectional shape, in which a width is gradually made wider toward an open end, and the gas spouts 42 are opened in inner bottom faces of the grooves 46. Since the gas spouts 42 are opened in the tapered grooves 46, the reaction gas can be effectively dissociated. Note that, in the present embodiment too, the grooves 46 may have inverse tapered sectional shapes.

Since a milling cutter can form the grooves 46, the electrode plate 40 can be easily produced.

(Operation of The Chemical Vapor Deposition Apparatus)

Operation of the chemical vapor deposition apparatus shown in FIG. 1 will be explained.

The work piece 20 is transferred into the processing chamber 10 and supported by the supporting plate 22. Optionally, the support plate 22 can be the heater 25 itself. The heater 25 heats the work piece 20 until reaching predetermined temperature, then the work piece 20 is moved upward, by an elevating unit, until entering the opening 24a of the shielding plate 24. When the work piece 20 enters the opening 24a of the shielding plate 24, a small space is formed between an outer circumferential face of the work piece 20 and an inner circumferential face of the opening 24a.

In the processing chamber 10, the reaction gas is supplied from the gas-supplying unit G to the rear side of the electrode plate 40 via the gas inlet 12. The reaction gas is spouted toward the work piece 20 from the gas spouts 42 of the electrode plate 40. Simultaneously, radio frequency energy is applied to the electrode plate 40 by the radio frequency generator 18, so that plasma is produced in a space between the work piece 20 and the electrode plate 40. Therefore, the film can be formed on the work piece 20.

Note that, in the present embodiment, an operator is capable of selecting radio frequency energy from 100 KHz to 100 MHz to the electrode plate 40.

Radiofrequency energy can be selectively applied to the electrode plate 40 only, the work piece 20 (the supporting plate 22) only, or both of them simultaneously. In the present embodiment, the radio frequency energy application pattern can be selected from three patterns: (1) a radio frequency energy is applied to the electrode plate 40, and a different radio frequency energy is applied to the work piece 20; (2) superposed waves of two different radio frequency energy are applied to the electrode plate 40 only; and (3) the superposed waves are applied to the work piece 20 only.

As described above, the chemical vapor deposition apparatus of the present embodiment has the electrode plate 40, in which the ends of the gas spouts 42 are included in the grooves. Therefore, the ionization efficiency of the reactants is enhanced to form a film.

The invention may be embodied in other specific forms without departing from the spirit of essential characteristics thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

What is claimed is:

1. A chemical vapor deposition apparatus comprising a processing chamber and an electrode plate being provided in said processing chamber, wherein a work piece is provided in said processing chamber to face said electrode plate parallel, reactants are spouted from said electrode plate toward the work piece with applying radio frequency energy between said electrode plate and the work piece so as to produce plasma there between to process the work piece, said chemical vapor deposition apparatus being characterized in,
That said electrode plate has a plate proper including a plurality of gas spouts, which run through the plate proper in the thickness direction thereof, and
That the gas spouts are opened in inner bottom faces of any grooves, which are formed in a surface of the plate proper facing the work piece and extended to linearly transect the plate proper.

2. The apparatus according to claim 1,
wherein a planar arrangement of the gas spouts in the plate proper is realized and
all of the grooves are mutually arranged parallel.

3. The apparatus according to claim 1,
wherein a planar arrangement of the gas spouts in the plate proper is realized and
the grooves are divided into three groups, in each of which the grooves are arranged parallel and which are mutually crossed at crossing angles of 60 degrees.

4. The apparatus according to claim 1,
wherein a planar arrangement of the gas spouts in the plate proper is realized and
the grooves are divided into two groups, in each of which the grooves are arranged parallel and which are mutually crossed at crossing angles of 90 degrees.

5. The electrode plate of the apparatus of according to claim 2,
wherein a planar arrangement of the gas spouts in the plate proper is realized and
all of the grooves are mutually arranged parallel.

6. The electrode plate of the apparatus of according to claim 3,
wherein a planar arrangement of the gas spouts in the plate proper is realized and
the grooves are divided into three groups, in each of which the grooves are arranged parallel and which are mutually crossed at crossing angles of 60 degrees.

7. The electrode plate of the apparatus of according to claim 4,
wherein a planar arrangement of the gas spouts in the plate proper is realized and
the grooves are divided into two groups, in each of which the grooves are arranged parallel and which are mutually crossed at crossing angles of 90 degrees.

8. The electrode plate of the apparatus of according to claim 5,
wherein each of the grooves has a tapered sectional shape, in which a width of an open end is greater than that of an inner end.

9. The electrode plate of the apparatus of according to claim 6,
wherein each of the grooves has a tapered sectional shape, in which a width of an open end is greater than that of an inner end.

10. The electrode plate of the apparatus of according to claim 7,
wherein each of the grooves has a tapered sectional shape, in which a width of an open end is greater than that of an inner end.

11. The electrode plate of the apparatus of according to claim 5,
wherein each of the grooves has an inverse tapered sectional shape, in which a width of an open end is smaller than that of an inner end.

12. The electrode plate of the apparatus of according to claim 6,
wherein each of the grooves has an inverse tapered sectional shape, in which a width of an open end is smaller than that of an inner end.

13. The electrode plate of the apparatus of according to claim 7,
wherein each of the grooves has an inverse tapered sectional shape, in which a width of an open end is smaller than that of an inner end.
